(19) United States
(12) Patent Application Publication
(10) Pub. No.: US 2020/0259308 A1
(43) Pub. Date: Aug. 13, 2020

(54) LIGHT-EMITTING ELEMENT AND METHOD FOR MANUFACTURING THE SAME

(71) Applicant: SHARP KABUSHIKI KAISHA, Sakai City (JP)

(72) Inventors: MASAHIRO KATO, Sakai City (JP); MASAYA ISHIDA, Sakai City (JP); AKIRA ARIYOSHI, Sakai City (JP); AKINORI NOGUCHI, Sakai City (JP)

(21) Appl. No.: 16/781,874

(22) Filed: Feb. 4, 2020

Related U.S. Application Data
(60) Provisional application No. 62/803,348, filed on Feb. 8, 2019.

(51) Int. Cl. H01S 5/028

(52) U.S. Cl. CPC H01S 5/028

(57) ABSTRACT

A light-emitting element includes: a substrate; a semiconductor chip, formed over the substrate, that includes a plurality of semiconductor layers; a first protective film formed on a first end face of the semiconductor chip that includes a luminous point from which light is emitted; and a first light-absorbing film formed on a part of a surface of the first protective film. The first light-absorbing film covers a part of the surface of the first protective film excluding a portion of the surface through which light emitted from the luminous point passes.

### TECHNICAL FIELD

The present invention relates to a light-emitting element and a method for manufacturing the same.

### BACKGROUND ART

For example, PTL 1 discloses a light-emitting element including granular light-absorbing films on top of an end face through which light from a laser chip is emitted and a technology with which to reduce the adhesion of contaminants to the element by directly irradiating, with laser light, a first light-absorbing film provided, in granular form on an optical axis of a laser.

### CITATION LIST

### Patent Literature

[PTL 1] Japanese Unexamined Patent Application Publication No. 2012-231189

### SUMMARY OF INVENTION

### Technical Problem

However, the technology according to PTL 1 produces losses of light by the absorption into the first light-absorbing film of a portion of the output of laser light, as the granular light-absorbing film is disposed on the optical axis of the laser.

One aspect of the present invention attains a light-emitting element that maintains its resistance to contaminants in the atmosphere without producing losses of laser light and a method for manufacturing the same.

### Solution to Problem

A light-emitting element according to one aspect of the present invention includes: a substrate; a semiconductor chip, formed over the substrate, that includes a plurality of semiconductor layers; a first protective film formed on a first end face of the semiconductor chip that includes a luminous point from which light is emitted; and a first light-absorbing film formed on a part of a surface of the first protective film, the light-emitting element being characterized in that the first light-absorbing film covers a part of the surface of the first protective film located on an optical axis of the light and excluding a portion of the surface through which light emitted from the luminous point passes.

A light-emitting element according to one aspect of the present invention is characterized in that the first light-absorbing film generates heat by absorbing light.

A light-emitting element according to one aspect of the present invention is characterized in that the first light-absorbing film is made of metal.

A light-emitting element according to one aspect of the present invention is characterized in that the light-emitting element emits light whose wavelength is 535 nm or shorter.

A light-emitting element according to one aspect of the present invention further includes: a second protective film formed on a second end face of the semiconductor chip that faces the first end face; and a second light-absorbing film formed on a surface of the second protective film.

A light-emitting element according to one aspect of the present invention is characterized in that the second light-absorbing film covers a part of the surface of the second protective film excluding a portion of the surface through which light emitted from the luminous point passes.

A method for manufacturing a light-emitting element according to one aspect of the present invention includes the steps of: forming, over a substrate, a semiconductor chip including a plurality of semiconductor layers; forming a first protective film on a first end face of the semiconductor chip that includes a luminous point from which light is emitted; and forming a first light-absorbing film on a part of a surface of the first protective film, the method being characterized in that the first light-absorbing film is formed so cover a part of the surface of the first protective film excluding a portion of the surface through which light emitted from the luminous point passes.

A method for manufacturing a light-emitting element according to one aspect of the present invention is characterized in that the step of forming the first light-absorbing film is formed by sputtering or deposition, and that the semiconductor chip is fixedly held between two spacers so that the surface of the first protective film is backed off inward from ends of the spacers, and the first light-absorbing film is formed with the surface of the first protective film placed at a tilt with respect to a direction of a material beam that is emitted from a material source of the sputtering or the deposition.

### BRIEF DESCRIPTION OF DRAWINGS

FIG. 1 is a perspective view schematically showing a light-emitting element according to an embodiment of the present invention and a package in which to accommodate the light-emitting element.

FIG. 2A is a cross-sectional view schematically showing a configuration of a light-emitting element according to an embodiment of the present invention as seen from a direction perpendicular to a direction of emission of light.

FIG. 2B is a cross-sectional view schematically showing a configuration of a semiconductor chip according to the embodiment of the present invention as seen from the direction of emission of light.

FIG. 3 is a table of measurements of thicknesses of contaminants with respect to emission wavelengths of light-emitting elements according to embodiments of the present invention.

FIG. 4 is a graph of measurements of thicknesses of contaminants with respect to emission wavelengths of light-emitting elements according to embodiments of the present invention.

FIG. 5 is a schematic view showing a method for forming a first light-absorbing film of a light-emitting element according to an embodiment of the present invention.

FIG. 6 is a cross-sectional view schematically showing a configuration of a conventional light-emitting element as seen from a direction perpendicular to a direction of emission of light.

### DESCRIPTION OF EMBODIMENTS

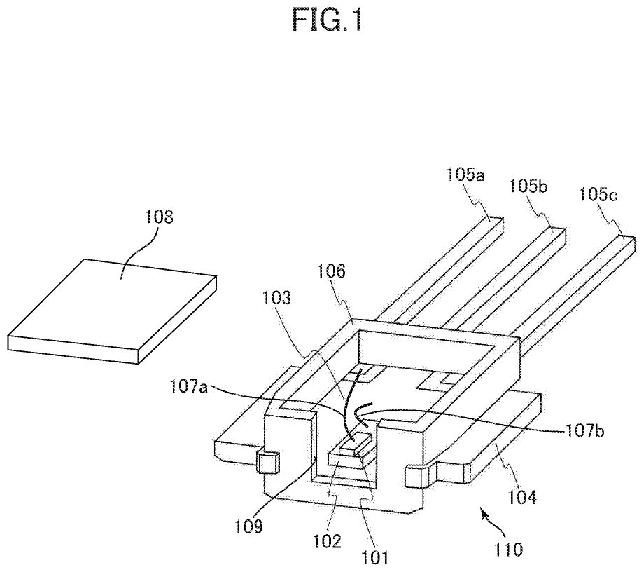

Embodiments of the present invention are described in detail below. FIG. 1 is a perspective view schematically showing a light-emitting element according to an embodiment of the present invention and a package in which to accommodate the light-emitting element.

As shown in FIG. 1, a package 110 according to the present embodiment is for example a frame-type package in which a light-emitting element is mounted on a planar frame, and includes a light-emitting element 101, a sub-mount 102 to which the light-emitting element 101 is fixed, a frame 103 to which the sub-mount 102 is fixed, heat dissipation fins 104 integrated with the frame 103 and provided at both ends, respectively, of the frame 103, lead pins 105a to 105c through which to supply electric power to the light-emitting element 101 (laser chip) 101, and a resin mold 106 that retains the lead pins 105a to 105c and the frame 103 as a unit. In the present embodiment, the light-emitting element 101 is for example a semiconductor laser.

Further, the light-emitting element 101 has one electrode electrically connected to the lead pin 105a via a wire 107a and another electrode electrically connected to the sub-mount 102 by die bonding, and the sub-mount 102 and the lead pin 105b are electrically connected to each other via a wire 107b.

Further, the package 110 has its top surface closed by a cap 108, which protects the light-emitting element 101 and the wires 107a and 107b. Further, the package 110 has an aperture 109 through which light emitted by the light-emitting element 101 is emitted outward, and the light-emitting element 101 is exposed through the aperture 109 to the outside atmosphere.

The sub-mount 102, which serves mainly to dissipate heat generated from the light-emitting element 101, may be omitted, provided that the heat dissipation characteristics of the light-emitting element 101 are secured. Further, the heat dissipation fins 104 may too be omitted, provided that the heat dissipation characteristics of the light-emitting element 101 are secured.

Further, in the first embodiment, the lead pins 105a to 105c are configured such that electric power is supplied only to the lead pins 105a and 105b and no electric power is supplied to the lead pin 105c. Alternatively, the lead pin 105c may be excluded so that only the two lead pins 105a and 105b axe provided, or a photodetector or a semiconductor layer laser may be additionally disposed so that electric power is supplied through the lead pin 105c to the photodetector or the semiconductor layer laser thus added.

Further, the cap 108 may be omitted, provided that the light-emitting element 101 and the wires 107a and 107b are protected by a housing other than the package 110.

Further, the aperture 109, through which the package 110 is exposed to the outside atmosphere, may be sealed with a transparent glass or resin through which light emitted by the light-emitting element 101 is emitted outward. Even in a case where the aperture 109 is sealed with a transparent glass or resin, a decontamination effect can be brought about, as contaminants produced from an inner wall or the like of the package 110 thus hermetically sealed may adhere to the light-emitting element 101.

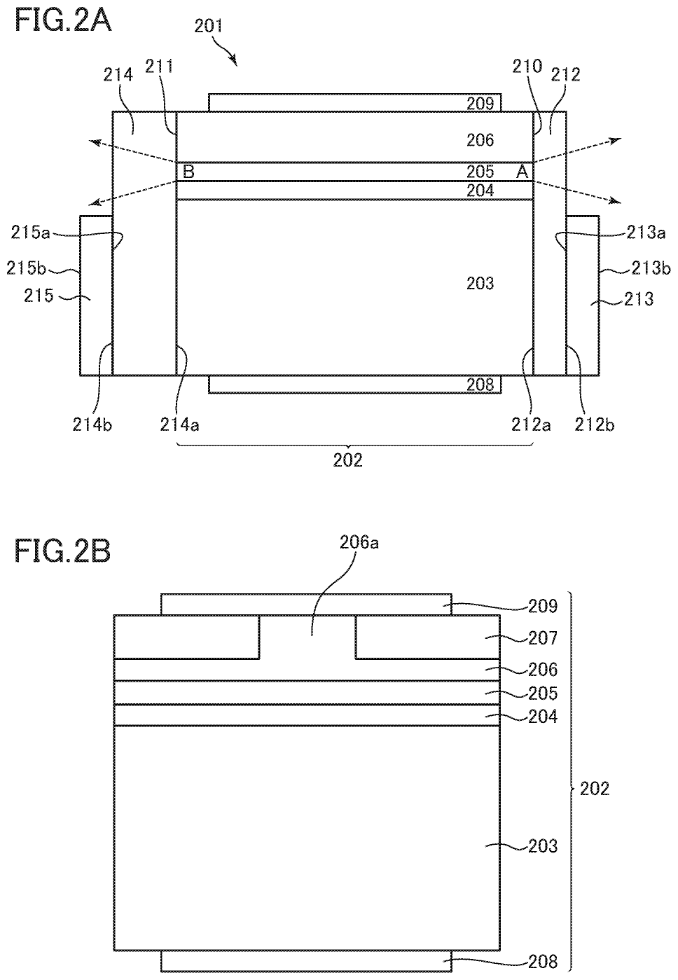

FIG. 2A is a cross-sectional view schematically showing a configuration of a light-emitting element 201 according to an embodiment of the present invention as seen from a direction perpendicular to a direction of emission of light. Further, FIG. 2B is a cross-sectional view schematically showing a configuration of a semiconductor chip 202 according to the present embodiment as seen from the direction of emission of light.

As shown in FIGS. 2A and 2B, the light-emitting element 201 is for example an end-face-emitting semiconductor laser element that emits laser light through an end face. The light-emitting element 201 includes at least the semiconductor chip 202, a first protective film 212, and a first light-absorbing film 213.

The semiconductor chip 202 includes a substrate 203 and a plurality of semiconductor layers formed over the substrate 203. The plurality of semiconductor layers are for example a lower clad layer 204, a luminescent layer 205, and an upper clad layer 206.

The upper clad layer 206 has a projection 206a. The projection 206a of the upper clad layer 206 is in the shape of a stripe when seen from above the semiconductor chip 202. The projection 206a of the upper clad layer 206 serves as a waveguide that confines an electrical current and light. Formed on both sides of the projection 206a of the upper clad layer 206 are dielectric films 207.

Formed at the bottom of the substrate 203 is a lower electrode 208. Formed above the upper clad layer 206 is an upper electrode 209. Further, the semiconductor chip 202 has a plurality of surfaces that include first and second end faces 210 and 211 through which laser light is emitted, and the first end face 210 and the second end face 211 face each other.

The first protective film 212, formed over the first end face 210, has a surface 212a in contact with the first end face 210. Further, the first light-absorbing film 213, formed on a part of another surface 212b of the first protective film 212, has a surface 213a in contact with the surface 212b of the first protective film 212.

In the embodiment, the light-emitting element 201 emits light with the luminescent layer 205 when supplied with electric power from an outside source. The light is amplified by the waveguide, the first end face 210, and the second end face 211 so that laser light is emitted from a luminous point A. The laser light thus emitted is emitted outward through the first protective film 212.

Note here that the substrate 203 is made of a material that supports the light-emitting element 201. For example, the substrate 203 is made of Si-added n-type GaN. Instead of being made of the aforementioned material, the substrate 203 may be made, for example, of sapphire or Si.

The lower clad layer 204 is made of a material that confines light of laser oscillation to the luminescent layer 205, which will be described later. The lower clad layer 204 is made, for example, of Si-added n-type AlGaN. Instead of being made of the aforementioned material, the lower clad layer 204 may be made, for example, of n-type GaN, n-type AlInGaN, or the like.

It should be noted that a buffer layer may be provided between the substrate 203 and the lower clad layer 204. The buffer layer is made of a material that improves the surface smoothness of a semiconductor layer. The buffer layer is made, for example, of Si-added n-type Gat or the like.

The luminescent layer 205 is made of a material that has a quantum well and in which a luminescent recombination of electrons and holes takes place. Further, the luminescent layer 205 may be a multiple quantum well layer composed of a plurality of barrier layers and well layers. The barrier layers are made, for example, of undoped GaN, and the well layers are made, for example, of undoped InGaN. The mixed crystal ratios of the well layers can be arbitrarily adjusted according to the wavelength of a laser that oscillates. Instead of being made of the aforementioned materials, the luminescent layer 205 may have its barrier layers made, for example, of undoped AlGaN and have its well layers made, for example, of GaN, AlGaN, or the like.

It should be noted that a lower guide layer may be provided between the lower clad layer 204 and the luminescent layer 205. The lower guide layer is made of a material that confines oscillating laser light to the luminescent layer 205. The lower guide layer is made, for example, of undoped InGaN. The lower guide layer may or may not have an n-type dopant added during stacking.

The upper clad layer 206 is made of a material that confines oscillating laser light to the luminescent layer 205. The upper clad layer 206 is made, for example, of Mg-added p-type AlGaN. The waveguide (projection 206a) formed on the upper clad layer 206 is in the shape of a stripe in a longitudinal direction when seen from above the laser element and functions to confine carriers and light produced in the luminescent layer 205. Instead of being made of the aforementioned material, the upper clad layer 206 may be made, for example, of p-type GaN, p-type AlInGaN, or the like.

It should be noted that an upper guide layer may be provided between the luminescent layer 205 and the upper clad layer 206. The upper guide layer is made of a material that confines oscillating laser light to the luminescent layer 205. The upper guide layer is made, for example, of undoped InGaN. The upper guide layer may or may not have a p-type dopant added during stacking.

The dielectric films 207 are formed to cover parts of an upper surface and side surfaces of the upper clad layer 206 exposed on both sides of the waveguide (projection 206a). Further, the dielectric films 207 are made of a material having electric insulation properties, and contain, for example, aluminum oxide, silicon oxide, zirconia, silicon nitride, aluminum nitride, gallium nitride, silicon oxynitride, or the like.

The lower electrode 208 may be one or more layers formed to cover at least a part of a lower surface of the substrate 203. The lower electrode 208 is made of a material that makes electrical contacts with the substrate 203, and contains, for example, Ti, N, Ta, Nb, Ni, Pt, or the like.

The upper electrode 209 may be one or more layers formed to cover at least a part of an upper surface of the waveguide (projection 206a). Further, the upper electrode 209 may also cover at least parts of upper surfaces of the dielectric films 207. The upper electrode 209 is made of a material that makes electrical contacts with the upper clad layer 206, and contains, for example, Ti, N, Ta, Nb, Ni, Pt, or the like.

It should be noted that the lower electrode 208 and the upper electrode 209 do not necessarily need to be disposed in lower and upper positions that face each other across the luminescent layer 205. For example, when the substrate 203 is made of sapphire, which conducts no electricity, the lower electrode 208 may be formed on a part of the lower clad layer exposed by etching or the like and be disposed on the same side of the luminescent layer 205 as the upper electrode 209. Further, the semiconductor chip 202 may be turned upside down to be in a so-called junction down arrangement.

It should be noted that a contact layer may be provided between an upper surface of the waveguide of the upper clad layer 206 and the upper electrode 209. The contact layer is made, for example, of a material that makes electrical contacts with the upper electrode 209. The contact layer is made, for example, of Mg-added GaN. Further, the contact layer forms the waveguide as is the case with a part of the upper clad layer 206.

The first protective film 212 protects the first end face 210 of the semiconductor chip 202, reflects a portion of the laser light with an arbitrary reflectance, and transmits a portion of the laser light. The first protective film 212 is made of a material arbitrarily selected according to the wavelength of laser light that oscillates, and is constituted, for example, by appropriately selecting and stacking aluminum oxynitride (AlON), silicon nitride (SiN), and aluminum oxide (Al₂O₃).

The first light-absorbing film 213 is made of a material selected from among materials that generate heat by absorbing light, and is constituted, for example, by a material appropriately selected from materials such as silicon, titanium, palladium, gold, copper, rhodium, iridium, osmium, ruthenium, and platinum.

It is preferable that the first light-absorbing film 213 cover at least a part of the surface 212b of the first protective film 212 located on an optical axis of the light and excluding a portion of the surface 212b through which light passes, and it is preferable that the first light-absorbing film 213 be formed to planarly cover a region of the surface 212b located below the luminescent layer 205, i.e. at least a part of the surface 212b that faces the substrate 203. The embodiment, in which oscillating laser light is not blocked by the first light-absorbing film 213, produces less losses of light than in a case where the first light-absorbing film 213 is not planar but granular and the adhesion of contaminants to the element is reduced by absorbing laser light.

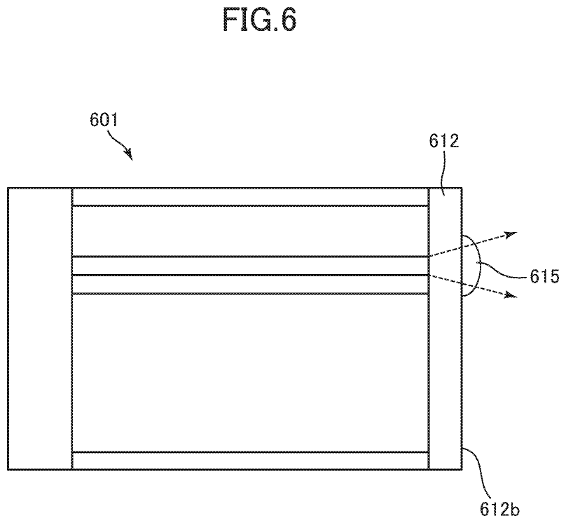

In addition, by covering at least the part of the surface 212b of the first protective film 212 excluding the portion of the surface 12b through which laser light passes, the first light-absorbing film 213 prevents accumulation of contaminants adhering to the surface 212b of the first protective film. This enables oscillation of a laser with stable light output even after a long period of use. Concrete descriptions are given below with reference to FIG. 6.

As shown in FIG. 6, when a conventional semiconductor laser element 601 is used under exposure to the atmosphere, contamination-producing substances such as siloxane and hydrocarbon compounds adhere to a surface 612b of a protective film 612. A portion of the siloxane that has adhered leaves again from the surface 612b of the protective film under ambient heat. However, another portion of the siloxane that has adhered is decomposed upon irradiation with laser light and produce silicon oxides, such as SiO₂ and SiO, that are firmly fixed as contaminants 615 to a portion of the surface 612b of the protective film through which the laser light passes. Since the contaminants 615 block the laser light, a feedback is applied to make tele light output constant and a rise in drive current takes place. This ends up in a vicious cycle of further accumulation of contaminants.

In the embodiment, as shown in FIG. 2A, the first light-absorbing film 213 covers at least the part of the surface 212b of the first protective film 212 located on the optical axis of the light and excluding the portion of the surface 212b through which light passes. Note here that the light emitted by the luminescent layer 205 includes light that does not contribute to laser oscillation, e.g. light that has leaked out to the lower clad layer 204 and the substrate 203. This light is called stray light, which repeats reflections within the semiconductor chip 202. The first light-absorbing film 213 absorbs this stray light. Although FIG. 2A illustrates an example in which the first light-absorbing film 213 is formed to cover one end of the substrate 203 via the first protective film 212, the first light-absorbing film 213 may be formed to cover as far as one end of the lower clad layer 204.

The first light-absorbing film 213 generates heat by absorbing a part or the whole of light of the same wavelength as the light emitted from the luminous point A and transfers the heat thus generated to a portion of the surface 212b of the first protective film 212 through which the light emitted from the luminous point A passes. This promotes the desorption of the siloxane and the like adhering to the surface 212b of the first protective film 212, whose temperature has risen, and results in the prevention of accumulation of silicon oxides or the like on the surface 212b of the first protective film 212. In addition, planarly mounting the first light-absorbing film 213 allows the first light-absorbing film 213 to completely absorb stray light having passed through the first protective film 212, thus making it possible to more surely transfer generated heat than granularly mounting a first light-absorbing film.

It is preferable that the first light-absorbing film 213 be made of a material selected from among materials that absorb light of the same wavelength as the light emitted from the luminous point A, and in the case of a light-emitting element that emits laser light with a wavelength of 535 nm or shorter, examples of the materials include silicon, titanium, gold, and the like. By being made of a material selected from among materials that absorb light of the same wavelength as the light emitted from the luminous point A, the first light-absorbing film 213 can surely absorb tray light, which repeats reflections within the semiconductor chip 202.

Further, it is preferable that the first light-absorbing film 213 be made of metal. By being made of metal, the first light-absorbing film 213 causes the surface 212b of the first protective film 212 to hardly become charged and function less to collect dust. This further reduces the adhesion of siloxane and the like to the surface 212b of the first protective film 212, thus preventing accumulation of silicon oxides or the like.

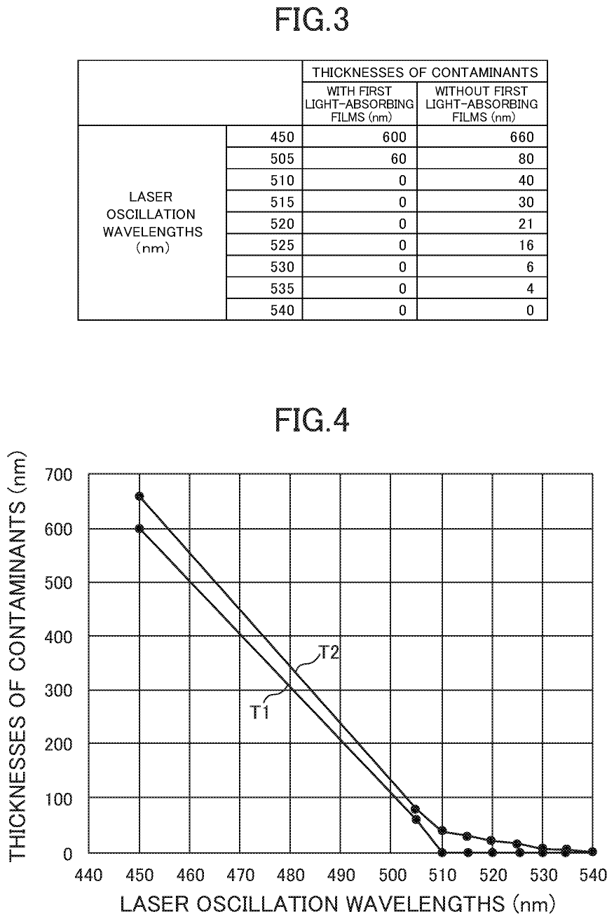

Further, it is preferable that the wavelength of light that is emitted be 535 nm or shorter. FIG. 3 is a table of measurements of thicknesses of contaminants accumulating on the first protective films 212 after embodiments of different oscillation wavelengths and light-emitting elements having no first light-absorbing films have been driven for 500 hours with a light output of 30 mW. The measurements of the thicknesses of the contaminants are taken by a TEM (transmission electron microscope) measuring thicknesses of the highest portions of the accumulated contaminants with reference to the surfaces 212b of the first protective films 212.

As shown in FIG. 3, in the presence of first light-absorbing films, on the one hand, accumulation of contaminants was observed at laser oscillation wavelength of 450 nm and 505 nm, but in the absence of first light-absorbing films, less contaminants accumulated. Furthermore, accumulation of contaminants was not observed at laser oscillation wavelengths of 510 nm, 515 nm, 520 nm, 525 nm, 530 nm, and 535 nm.

In the absence of first light-absorbing films, on the other hand, accumulation of contaminants was observed at laser oscillation wavelengths of 450 nm, 505 nm, 510 nm, 515 nm, 520 nm, 525 nm, 530 nm, and 535 nm, and accumulation of contaminants was not observed at a laser oscillation wavelength of 540 nm. That is, at a laser oscillation wavelength of 535 nm or shorter, for example, 535 nm, 530 nm, 525 nm, 520 nm, 515 nm, 510 nm, 505 nm, and 450 nm, the embodiments are smaller in thickness of contaminants than the semiconductor laser elements having no first light-absorbing films and prevent accumulation of contaminants on the surfaces 212b of the first protective films 212, reducing losses of laser light.

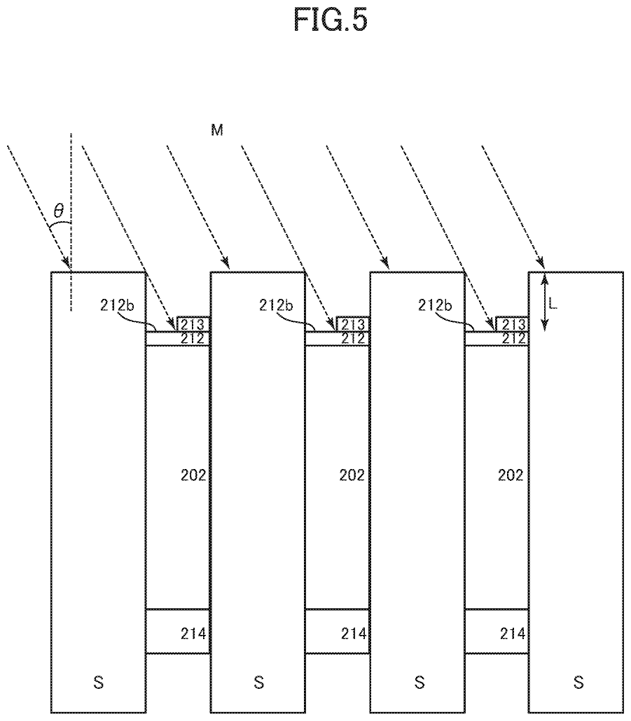

Further, for complete prevention of accumulation of contaminants on the surface 212b of the first protective film 212, it is preferable that the wavelength of light that is emitted be in a range of 510 nm or longer to 535 nm or shorter. Concrete description are given below with reference to FIG. 4.

FIG. 4 is a graph of measurements of thicknesses of contaminants accumulating on the surfaces 212b of the first protective films 212 after embodiments of different oscillation wavelengths have been driven for 500 hours with a light output of 30 mW. The measurements of the thicknesses of the contaminants conform to the table shown in FIG. 3. In FIG. 4, the sign T1 denotes a graph representing cases where first light-absorbing films are present, and the sign T2 denotes a graph representing cases where first light-absorbing films are absent.

When the oscillation wavelength of a laser is in a range of 510 nm or longer to 535 nm or shorter, no contaminants are accumulated on the surface 212b of the first protective film 212. When the oscillation wavelength of a laser is shorter than 510 nm, the light energy of laser light becomes so great that contamination-producing substances having adhered to the surface 212b of the first protective layer becomes active in reacting under light. For this reason, the speed at which the contamination-producing substances chemically react under light becomes higher than the speed at which the contamination-producing substances leave from the surface 212b of the first protective film 212 under heat; therefore, accumulation of contaminants is not completely prevented, although the first light-absorbing film 213 brings about a certain effect of reducing accumulation of contaminants.

Further, when the oscillation wavelength of a laser is longer than 535 nm, the light energy of laser light becomes so small that it becomes hard for the contamination-producing substances to react under light; therefore, no contaminants are accumulated and it becomes hard to bring about an effect of the present embodiment. Accordingly, for complete prevention of accumulation of contaminants on the surface 212b of the first protective film 212, it is preferable that the wavelength of light that is emitted be in a range of 510 nm or longer to 535 nm or shorter.

It should be noted that as shown in FIG. 2A, a second protective film 214 may be formed over the second end face 211, which faces the first end face 210, and have a surface 214a in contact with the second end face 211.

Further, a second light-absorbing film 215 may be formed on a surface of the second protective film 214 and have a surface 215a in contact with a surface 214b of the second protective film 214. When supplied with electric power from an outside source, the light-emitting element 201 emits laser light from the luminous point A and, at the same time, also emits laser light from a luminous point B on the second end face 211. The laser light thus emitted is emitted outward through the second protective film 214.

The second protective film 214 protects the second end face 211, reflects a portion of the laser with a given reflectance, and transmits a portion of the laser light. Further, the second protective film 214 is formed with a higher reflectance than that of the first protective film 212 with respect to the wavelength of laser emission. The second protective film 214 may be made of a material arbitrarily selected according to the wavelength of laser light that oscillates, and may be formed, for example, by one or more layers from aluminum oxynitride (AlON), silicon nitride (SiN), silicon oxide (SiO₂), titanium oxide (TiO₂) and the like.

The second light-absorbing film 215 is made of a material selected from among materials that generate heat by absorbing light, and examples of the materials include silicon, titanium, palladium, gold, copper, rhodium, iridium, osmium, ruthenium, platinum, and the like.

Note here that it is preferable that the second light-absorbing film 215 cover a part of the surface 214b of the second protective film 214 excluding a portion of the surface 214b through which the light emitted from the luminous point B passes. By covering the part of the surface 214b of the second protective film 214 excluding the portion of the surface 212b through which the light emitted from the luminous point B passes, the second light-absorbing film 215 prevents accumulation of contaminants adhering to the surface 214b of the second protective film 214. Therefore, in a case where a photodetector is mounted on an optical axis of a laser on the side of the second end face 211 to monitor light output from the semiconductor laser device, there are less extra feedback for stabilizing the light output, as accumulation of contaminants causes no reduction in light output on the side of the second end face 211.

### Method for Manufacturing Light-Emitting Element

Next, an example of a method for manufacturing a light-emitting element according to the present embodiment is described. The following describes, as an example, a method for manufacturing a nitride semiconductor laser element using an MOCVD method (metalorganic chemical vapor deposition method).

First, a plurality of semiconductor layers are stacked on a substrate. Specifically, for example, a substrate 203 composed of Si—GaN in a wafer shape is placed into an MOCVD apparatus, and a lower clad layer 204 composed of Si—Al_{0.01}Ga_{0.99}N is formed with a thickness of 1.5 μm.

Next, a luminescent layer 205 is formed. Specifically, for example, a barrier layer composed of non-doped GaN and a well layer composed of non-doped InGaN are repeatedly stacked twice, and another barrier layer composed of non-doped GaN is stacked. The crystal ratio and layer thickness of each of the well layers are appropriately adjusted so that a laser oscillates at a wavelength of 520 nm.

Next, an upper clad layer 206 is stacked. Specifically, for example, an upper clad layer 206 composed of Mg—Al_{0.05}Ga_{0.95}N is stacked with a thickness of 1 μm, and the substrate is taken out from the MOCVD apparatus with the plurality of semiconductor layers stacked thereon, whereby a wafer is obtained.

Next, a waveguide is formed on the wafer having the plurality of semiconductor layers stacked thereon. The waveguide is formed by an arbitrary photolithography method and an etching method. Specifically, for example, a portion on the wafer that is equivalent to the waveguide is masked by a photoresist, and an unmasked upper clad layer is removed by dry etching down to an arbitrary depth. Finally, the mask is removed, whereby the wafer having the waveguide formed thereon is obtained.

Next, dielectric films 207 are formed on a surface of the upper clad layer and side surfaces or the waveguide of the wafer having the waveguide formed thereon, with the surface and the side surfaces exposed by etching. The dielectric films 207 are formed by an arbitrary method. Specifically, for example, first, SiO₂ is formed on a wafer surface by an electron cyclotron resonance plasma chemical vapor deposition (ECR plasma CVD) method. Next, SiO₂ on the waveguide is removed by a photolithography method, whereby the wafer having the dielectric films 207 formed thereon is obtained.

Next, a lower electrode 208 and an upper electrode 209 are formed on the wafer having the dielectric films 207 formed thereon. The lower electrode 208 and the upper electrode 209 are formed by an arbitrary method. Specifically, for example, Ti/Au is stacked on both surfaces of the wafer by vapor deposition, and then the wafer having the lower and upper electrodes 208 and 209 patterned thereon by a photolithography method is obtained.

Next, the wafer-shaped substrate 203 having the lower and upper electrodes 208 and 209 formed thereon is divided into a bar shape, and a first end face 210 including a luminous point A from which light is emitted is formed The first end face 210 is formed by an arbitrary method. Specifically, for example, the wafer having the lower and upper electrodes 208 and 209 formed thereon is cleft at spacings equal to the length of a resonator of a semiconductor laser element 201 from a direction perpendicular to the waveguide, whereby a semiconductor chip 202 divided into a bar shape and having the plurality of semiconductor layers formed thereon is obtained. The bar-shaped semiconductor chip 202 has one plane of cleavage serving as the first end face 210 and another plane of cleavage serving as a second end face 211.

Next, a first protective film 212 is formed over the first end face 210. The first protective film 212 is formed by an arbitrary method. Specifically, for example, the first protective film 212 is obtained by stacking 20 nm of aluminum oxynitride (AlON), 80 nm of silicon nitride (SiN), and 140 nm of aluminum oxide (Al₂O₃) in this order on the first end face 210 by sputtering.

It should be noted that a second protective film 214 may be formed over the second end face 211. The second protective film 214 is formed by an arbitrary method. Specifically, for example, the second protective film 214 is obtained by forming 20 nm of aluminum oxynitride (AlON) and 80 nm of silicon nitride (SiN) on the second end face 211 by sputtering, further combining four sets of 70 nm of silicon oxide (SiO₂) and 50 nm of titanium oxide (TiO₂), and further stacking 150 nm of SiO₂ over TiO₂ of the fourth set.

Next, a first light-absorbing film 213 is formed on a part of a surface 212b of the first protective film 212. The first light-absorbing film 213 is formed to cover a part of the surface 212b of the first protective film 212 excluding a portion of the surface 212b through which the light emitted from the luminous point A passes. Specifically, for example, Ti is formed with a thickness of 100 nm on the part of the surface 212b of the first protective film 212 by a sputtering apparatus. At this point in time, the first light-absorbing film 213 is formed with the surface 212b of the first protective film 212 placed at a tilt with respect to a material beam of sputtering. More concrete descriptions are given below with reference to FIG. 5.

FIG. 5 is a schematic view showing a method for forming a first light-absorbing film 213 of an embodiment.

First, a bar-shaped semiconductor chip 202 having first and second protective films 212 and 214 formed thereon is fixedly held between two spacers S and placed on a stage in a sputtering apparatus (not illustrated).

There may be more than one bar-shaped semiconductor chip 202. In FIG. 5, three semiconductor chips 202 are alternately fixedly held between four spacers S. Note here that the semiconductor chips 202 are placed so that the surfaces 212b of the first protective films 212 face the upper side of the sputtering apparatus. Further, the surfaces 212b of the first protective films 212 are fixedly held between the spacers so as to be backed off inward from ends of the spacers, for example, by a distance L.

Note here that while the surface 212b of the first protective film 212 is conventionally placed perpendicularly to a direction of a material beam M that is emitted from a material source of the sputtering apparatus, the surface 212b of the first protective film 212 in the embodiment is placed at a tilt, for example, by an angle θ with respect to an optical axis direction of a material beam M that is emitted from a material source of the sputtering apparatus.

In the embodiment, the surface 212b of the first protective film 212 is horizontally placed on the sputtering apparatus and obliquely irradiated with the material beam M. Alternatively, the direction of irradiation with the material beam M may be fixed at a vertical direction so that the spacers S between which the semiconductor chip 202 is held may be fixed at a tilt or the stage of the sputtering apparatus may be fixed at a tilt. Further, while the embodiment involves the use of the sputtering apparatus, a deposition apparatus too makes it possible to place the surface 212b of the first protective film 212 at a tilt with respect to the direction of the material beam M to be emitted.

Note here that since the surface 212b of the first protective film 212 is fixedly held between the spacers S in a position backed off inward from the ends of the spacers S, for example, by the distance L, a part of the surface 212b of the first protective film 212 is shielded by end faces of the spacers S from being irradiated with the material beam M, with the result that no first light-absorbing film 213 is formed. Note here that when the portion of the surface 212b of the first protective film 212 that is shielded by the end faces of the spacers S from being irradiated with the material beam M is the portion of the surface 212b of the first protective film 212 through which the light emitted from the luminous point A passes, a first light-absorbing film 213 is formed to cover at least a part of the surface 212b of the first protective film 212 excluding the portion of the surface 212b through which the light emitted from the luminous point A passes.

It should be noted that a second light-absorbing film 215 may be formed by a method which is similar to that by which the first light-absorbing film 213 is formed. Specifically, for example, the semiconductor chip 202 may be fixedly held between two spacers S so that the surface 214b of the second protective film 214 is backed off inward from ends of the spacers S, and the second light-absorbing film 215 may be formed by sputtering or deposition with the surface 214b of the second protective film 214 placed at a tilt with respect to a direction of a material beam M that is emitted from a material source of the sputtering or the deposition.

Finally, the bar-shaped semiconductor chip 202 having the first light-absorbing film 213 formed thereon is divided into single elements by an arbitrary method, whereby a light-emitting element 201 such as that shown in FIG. 2A is formed.

Instead of using a frame-type package, the light-emitting elements of the embodiments may use a CAN-type package. In so doing, a portion through which light from the light-emitting element is emitted out of the CAN-type package may have an opening to the external environment that may be sealed with glass or resin.

Further, while the light-emitting elements of the embodiments thus disclosed are end-face-emitting semiconductor laser elements, the present invention is applicable to various types of light-emitting element. For example, an end-face-emitting semiconductor laser element may be replaced by a surface-emitting laser having a first protective film 212 formed on a plane of emission thereof and a first light-absorbing film formed on a part of the first protective film 212 that is not an optical axis or by an LED having a first protective film 212 formed on an emission surface thereof and a first light-absorbing film formed on a part of the first protective film 212.

Alternatively, a combination of a laser light source and a frequency converting element may have a first protective film 212 formed on a place of emission of the frequency converting element and a first light-absorbing film formed on a part of the first protective film 212 that is not an optical axis. Further, instead of being made of nitride semiconductors, the light-emitting elements may also be made of AlGaInAsP semiconductors or ZnSe semiconductors.

The present invention is not limited to any of the embodiments described above but may be altered in various ways within the scope of the claims, and an embodiment based on a proper combination of technical means disclosed in different embodiments is encompassed in the technical scope of the present invention. Furthermore, a new technical feature can be formed by a combination of technical means respectively disclosed in embodiments.

1. A light-emitting element comprising:
a substrate;
a semiconductor chip, formed over the substrate, that includes a plurality of semiconductor layers;
a first protective film formed on a first end face of the semiconductor chip that includes a luminous point from which light is emitted; and
a first light-absorbing film formed on a part of a surface of the first protective film,
wherein the first light-absorbing film covers a part of the surface of the first protective film located on an optical axis of the light and excluding a portion of the surface through which light emitted from the luminous point passes.

2. The light-emitting element according to claim 1, wherein the first light-absorbing film generates heat by absorbing light.

3. The light-emitting element according to claim 1, wherein the first light-absorbing film is made of metal.

4. The light-emitting element according to claim 1, wherein the light-emitting element emits light whose wavelength is 535 nm or shorter.

5. The light-emitting element according to claim 1, further comprising:
a second protective film formed on a second end face of the semiconductor chip that faces the first end face; and
a second light-absorbing film formed on a surface of the second protective film.

6. The light-emitting element according to claim 5, wherein the second light-absorbing film covers a part of the surface of the second protective film excluding a portion of the surface through which light emitted from the luminous point passes.

7. A method for manufacturing a light-emitting element, the method comprising the steps of:
forming, over a substrate, a semiconductor chip including a plurality of semiconductor layers;
forming a first protective film on a first end face of the semiconductor chip that includes a luminous point from which light is emitted; and
forming a first light-absorbing film on a part of a surface of the first protective film,
wherein the first light-absorbing film is formed to cover a part of the surface of the first protective film excluding a portion of the surface through which light emitted from the luminous point passes.

8. The method according to claim 7, wherein the step of forming the first light-absorbing film is performed by sputtering or deposition, and
the semiconductor chip is fixedly held between two spacers so that the surface of the first protective film is backed off inward from ends of the spacers, and the first light-absorbing film is formed with the surface of the first protective film placed at a tilt with respect to a direction of a material beam that is emitted from a material source of the sputtering or the deposition.
